(19) United States
(12) Patent Application Publication
(10) Pub. No.: US 2022/0116018 A1
(43) Pub. Date: Apr. 14, 2022

(54) BULK-ACOUSTIC WAVE FILTER DEVICE

(71) Applicant: Samsung Electro-Mechanics Co., Ltd., Suwon-si (KR)

(72) Inventors: Jang Ho PARK, Suwon-si (KR); Yoo Sam NA, Suwon-si (KR); Young Sik HUR, Suwon-si (KR); Seung Wook PARK, Suwon-si (KR); Hwa Sun LEE, Suwon-si (KR); Won Kyu JEUNG, Suwon-si (KR)

(73) Assignee: Samsung Electro-Mechanics Co., Ltd., Suwon-si (KR)

(21) Appl. No.: 17/233,797

(22) Filed: Apr. 19, 2021

(30) Foreign Application Priority Data
Oct. 8, 2020 (KR) 10-2020-0129922

(51) Int. Cl. H03H 9/54; H03H 9/17; H03H 9/02

(52) U.S. Cl. CPC H03H 9/54; H03H 9/02102; H03H 9/173

(57) ABSTRACT

A bulk-acoustic wave filter device includes: a substrate; a resonance portion in which a cavity is disposed between the substrate and the resonance portion; and a cap configured to form an internal space together with the substrate, wherein filling gas including at least one of hydrogen gas and helium gas is filled in at least one of the cavity and the internal space formed by the substrate and the cap.

### CROSS-REFERENCE TO RELATED APPLICATIONS

This application claims the benefit under 35 USC § 119(a) of Korean Patent Application No. 10-2020-0129922 filed on Oct. 8, 2020, in the Korean Intellectual Property Office, the entire disclosure of which is incorporated herein by reference for all purposes.

### BACKGROUND

### 1. Field

The following description relates to a bulk-acoustic wave filter device.

### 2. Description of Related Art

As fifth generation (5G) mobile telecommunications are being actively implemented, communication devices, such as mobile phones, may implement a mix of 5G communications and existing fourth generation (4G) long term evolution (LTE) components. Additionally, a high frequency of 3˜6 GHz, and a high power that can cope with a high-power user equipment (HPUE) would be necessary for the fast communications demanded by 5G. Accordingly, a filter device used therefor is may be necessary to have high power and high heat dissipation properties along with a miniaturized form factor.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Inn a general aspect, a bulk-acoustic wave filter device includes a substrate; a resonance portion, in which a cavity is disposed between the substrate and the resonance portion; and a cap, configured to form an internal space together with the substrate, wherein filling gas including at least one of hydrogen gas and helium gas is filled in at least one of the cavity and the internal space formed by the substrate and the cap.

The filling gas may be a mixture of the hydrogen gas and the helium gas.

The filling gas may be a mixture of the hydrogen gas and nitrogen gas.

The hydrogen gas or the helium gas may be 5% or more of the filling gas.

The resonance portion may include a first electrode, at least a portion of which is disposed on a top surface of the cavity; a piezoelectric layer, disposed to cover at least a portion of the first electrode; and a second electrode, at least a portion of which is disposed to cover the piezoelectric layer.

The bulk-acoustic wave filter device may further include an external connection electrode, disposed to penetrate through the substrate, and configured to be electrically connected to the first electrode and the second electrode.

The bulk-acoustic wave filter device may further include a membrane layer, configured to form the cavity together with the substrate, and on which the first electrode is disposed; an etch stop portion, disposed to surround the cavity; a passivation layer, disposed to cover a region of the resonance portion other than a region of the resonance portion where each of the first electrode and the second electrode are disposed; and a metal pad connected to each of the first electrode and the second electrode.

The bulk-acoustic wave filter device may further include an insertion layer, at least a portion of which is disposed between the piezoelectric layer and the first electrode.

In a general aspect, a bulk-acoustic wave filter device includes a package substrate; a volume acoustic resonator, mounted on the package substrate; and a cap, configured to form an internal space together with the package substrate, wherein the volume acoustic resonator includes a substrate, mounted on the package substrate; a first electrode, a cavity, disposed between the substrate and the first electrode; a piezoelectric layer, disposed to cover at least a portion of the first electrode; and a second electrode, disposed to cover at least a portion of the piezoelectric layer, and wherein filling gas, including at least one of hydrogen gas and helium gas, is filled in at least one of the cavity and the internal space formed by the package substrate and the cap.

The filling gas may be a mixture of the hydrogen gas and the helium gas.

The filling gas may be a mixture of the hydrogen gas and nitrogen gas.

The hydrogen gas or the helium gas may be 5% or more of the filling gas.

The volume acoustic resonator further may include a metal pad connected to each of the first electrode and the second electrode, and the package substrate may be configured to have a via connected to the metal pad by wire bonding.

The volume acoustic resonator may further include a metal pad connected to each of the first electrode and the second electrode, and the package substrate may be configured to have an inner wall portion in which a first via connected to the metal pad by wire bonding is formed.

The package substrate may be configured to have a second via connected to the first via, and the second via is exposed to a bottom surface of the package substrate.

The volume acoustic resonator may further include a membrane layer, configured to form the cavity together with the substrate, and on which the first electrode is disposed; an etch stop portion, disposed to surround the cavity; a passivation layer, disposed to cover a region of the resonance portion other than a region of the resonance portion where each of the first electrode and the second electrode are disposed; a metal pad, connected to each of the first electrode and the second electrode; and an insertion layer, at least a portion of which is disposed between the piezoelectric layer and the first electrode.

In a general aspect, a bulk acoustic wave filter device includes a substrate; a resonance portion, comprising a first electrode, a piezoelectric layer, and a second electrode, arranged sequentially; a cavity, disposed between the first electrode and the substrate; and a cap, configured to form an internal space with the substrate, wherein a gas including at least one of hydrogen gas and helium gas is filled in the cavity and the internal space.

The gas may be a mixture of the hydrogen gas and nitrogen gas.

The hydrogen gas or the helium gas may be 5% or more of the gas.

Other features and aspects will be apparent from the following detailed description, the drawings, and the claims.

### BRIEF DESCRIPTION OF DRAWINGS

FIG. 1 is a schematic cross-sectional view illustrating an example bulk-acoustic wave filter device, in accordance with one or more embodiments.

FIG. 2 illustrates a heat dissipation path of an example bulk-acoustic wave filter device, in accordance with one or more embodiments.

FIG. 3 is a schematic cross-sectional view illustrating an example bulk-acoustic wave filter device, in accordance with one or more embodiments.

FIG. 4 illustrates a heat dissipation path of an example bulk-acoustic wave filter device, in accordance with one or more embodiments.

FIG. 5 is a schematic cross-sectional view illustrating an example bulk-acoustic wave filter device, in accordance with one or more embodiments.

FIG. 6 illustrates a heat dissipation path of an example bulk-acoustic wave filter device, in accordance with one or more embodiments.

Throughout the drawings and the detailed description, unless otherwise described or provided, the same drawing reference numerals will be understood to refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness, noting that omissions of features and their descriptions are also not intended to be admissions of their general knowledge.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Unless otherwise defined, all terms, including technical and scientific terms, used herein have the same meaning as commonly understood by one of ordinary skill in the art to which this disclosure pertains and after an understanding of the disclosure of this application. Terms, such as those defined in commonly used dictionaries, are to be interpreted as having a meaning that is consistent with their meaning in the context of the relevant art and the disclosure of this application, and are not to be interpreted in an idealized or overly formal sense unless expressly so defined herein.

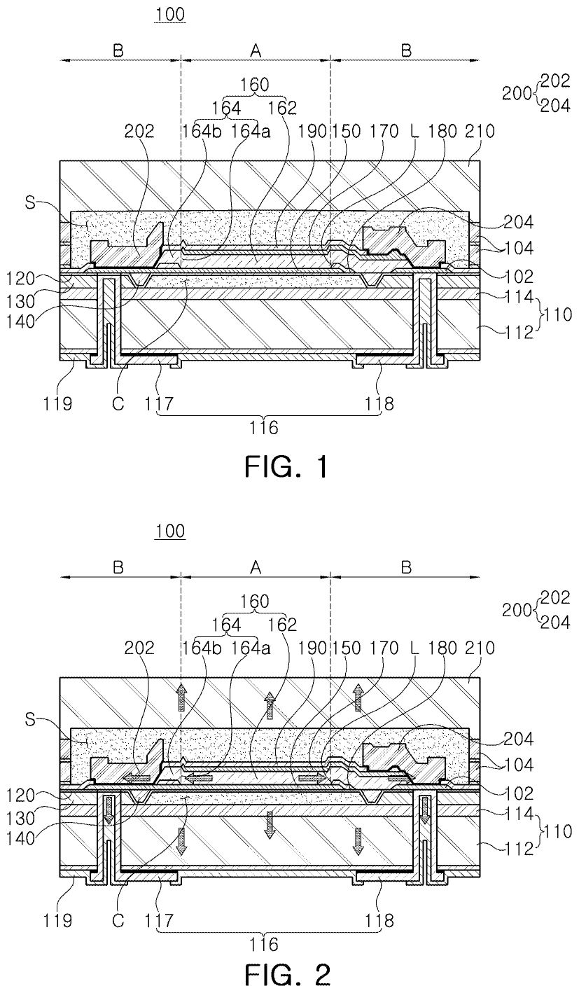

FIG. 1 is a schematic cross-sectional view illustrating an example bulk-acoustic wave filter device, in accordance with one or more embodiments.

Referring to FIG. 1, a bulk-acoustic wave filter device 100 according to an example may include a substrate 110, a membrane layer 120, a sacrificial layer 130, an etch stop portion 140, a first electrode 150, a piezoelectric layer 160, a second electrode 170, an insertion layer 180, a passivation layer 190, a metal pad 200 and a cap 210 for example.

The substrate 110 may include a base 112 and a substrate protective layer 114 formed on a top surface of the base 112. The base 112 may be a silicon substrate. In an example, the base 112 may use a silicon wafer or a silicon on insulator (SOI) type substrate.

The substrate protective layer 114 may be formed on the top surface of the base 112, and may thus serve to electrically isolate the base 112 by being disposed on the top surface of the base. Additionally, the substrate protective layer 114 may prevent the base 112 from being etched by etching gas when a cavity C is formed in a process of manufacturing the bulk-acoustic wave filter device 100.

In this example, the substrate protective layer 114 may be formed of at least one of silicon dioxide (SiO₂), silicon nitride (Si₃N₄), aluminum oxide (Al₂O₂) and aluminum nitride (AlN), and may be formed using any one of chemical vapor deposition, radio-frequency (RF) magnetron sputtering and evaporation.

In an example, an external connection electrode 116, which is connected to the first electrode 150 and the second electrode 170 of a resonance portion to be described below, may be formed on the substrate 110.

In an example, the external connection electrode 116 may include an electrode 117 for the first electrode 150 to connect the first electrode 150 externally, and an electrode 118 for the second electrode 170 to connect the second electrode 170 externally.

In an example, the electrode 117 for the first electrode 150 and the electrode 118 for the second electrode 170 may each be formed to penetrate through the substrate 110. In an example, the electrode 117 for the first electrode 150 may be directly connected to the first electrode 150, and the electrode 118 for the second electrode 170 may be connected to the second electrode 170 via the metal pad 200 and a connecting member 102.

An insulating layer 119 may be formed on each bottom surface of the external connection electrode 116 and the substrate 110 except for a region in which a portion of the external connection electrode 116 is externally exposed. The insulating layer 119 may be formed of a polymer material.

Additionally, the external connection electrode 116 may discharge heat generated by the resonance portion externally.

In an example, the external connection electrode 116 may be formed on the substrate 110. However, the external connection electrode 116 is not limited thereto, and may be connected externally through the cap 210. That is, the external connection electrode 116 may be connected to the metal pad 200, and may penetrate through the cap 210 to be exposed to an outer surface of the cap 210.

In an example, the connection electrode 116 may be a through silicon via (TSV).

The membrane layer 120 may form the cavity C together with the substrate 110. Additionally, the membrane layer 120 may be made of a material having low reactivity with the etching gas when a portion of the sacrificial layer 130 is removed. The membrane layer 120 may implement a dielectric layer including any one of silicon nitride (Si₃N₄), silicon oxide (SiO₂), manganese oxide (MgO), zirconium oxide (ZrO₂), aluminum nitride (AlN), lead lithium titanate (PZT), gallium arsenide (GaAs), hafnium oxide (HfO₂), aluminum oxide (Al₂O₃), titanium oxide (TiO₂) and zinc oxide (ZnO).

A seed layer (not shown) made of aluminum nitride (AlN) may be formed on the membrane layer 120. That is, the seed layer may be disposed between the membrane layer 120 and the first electrode 150. The seed layer may be formed with a dielectric or metal having a hexagonal closed packed (HCP) crystal structure in addition to aluminum nitride (AlN). In an example, when made of the metal, the seed layer may be formed of titanium (Ti).

An example may be described in which the membrane layer 120 is provided as an example. However, only the seed layer may be provided without the membrane layer 120. In this example, the seed layer may form the cavity C with the substrate 110, and the first electrode 150 may be stacked on a top surface of the seed layer.

The sacrificial layer 130 may be formed on the substrate protective layer 114, and the cavity C and the etch stop portion 140 may be disposed in the sacrificial layer 130. The cavity C may be formed by removing a portion of the sacrificial layer 130 during the manufacturing process. As described above, since the cavity C is formed in the sacrificial layer 130, the first electrode 150 and the like disposed on a top surface of the sacrificial layer 130 may be formed to be flat.

The etch stop portion 140 may be disposed along a boundary of the cavity C. The etch stop portion 140 may stop etch from proceeding beyond an area of the cavity in a process of forming the cavity C.

The first electrode 150 may be formed on the membrane layer 120, and a portion of the membrane layer 120 may be disposed on a top of the cavity C. Additionally, the first electrode 150 may be used as either an input electrode or an output electrode for inputting or outputting an electrical signal such as a radio frequency (RF) signal.

The first electrode 150 may be made of an aluminum alloy material including, but not limited to, scandium (Sc) for example. In this manner, the first electrode 150 may be made of the aluminum alloy material including scandium (Sc), and thus have increased mechanical strength, thereby enabling high power reactive sputtering. Under this deposition condition, it is possible to prevent the first electrode 150 from having an increased surface roughness and to induce the piezoelectric layer 160 to have high orientation growth.

Additionally, the first electrode 150 may have increased chemical resistance by including scandium (Sc), which may compensate for a disadvantage occurring when the first electrode is made of pure aluminum. Further, it is possible to secure stability of a process such as a dry etching process or a wet etching process during the manufacturing. Furthermore, the first electrode 150 may easily be oxidized when made of the pure aluminum, but may be made of an aluminum alloy material including scandium, and thus have the improved chemical resistance against its oxidation.

However, the first electrode 150 is not limited thereto, and may be formed with a conductive material such as molybdenum (Mo) or an alloy thereof, for example. However, the first electrode 150 is not limited thereto, and may be made of a conductive material such as ruthenium (Ru), tungsten (W), iridium (Ir), platinum (Pt), copper (Cu), titanium (Ti), tantalum (Ta), nickel (Ni), chromium (Cr) or an alloy thereof.

The piezoelectric layer 160 may be formed to cover at least a portion of the first electrode 150 disposed on the top of the cavity C. The piezoelectric layer 160 may be a portion producing a piezoelectric effect that converts electrical energy into mechanical energy in the form of a bulk-acoustic wave, and may include aluminum nitride (AlN) for example.

Additionally, the piezoelectric layer 160 may be doped with a dopant such as a rare earth metal or a transition metal. In an example, the rare earth metal used as the dopant may include at least one of scandium (Sc), erbium (Er), yttrium (Y) and lanthanum (La). Further, the transition metal used as the dopant may include at least one of titanium (Ti), zirconium (Zr), hafnium (Hf), tantalum (Ta) and niobium (Nb). In addition, the piezoelectric layer 160 may also include magnesium (Mg) which is a divalent metal.

The piezoelectric layer 160 may include a piezoelectric portion 162 disposed on a flat portion A, and a bent portion 164 disposed on an extending portion B.

The piezoelectric portion 162 may be a portion directly stacked on a top surface of the first electrode 150. Therefore, the piezoelectric portion 162 may be interposed between the first electrode 150 and the second electrode 170 to form to be flat like the first electrode 150 and the second electrode 170.

The bent portion 164 may be defined as a region extending outwardly from the piezoelectric portion 162 and disposed within the extending portion B.

The bent portion 164 may be disposed on an insertion layer 180 to be described below, and may be formed to protrude in a shape of the insertion layer 180. Accordingly, the piezoelectric layer 160 may be bent at a boundary between the piezoelectric portion 162 and the bent portion 164, and the bent portion 164 may be uplifted corresponding to the thickness and shape of the insertion layer 180.

The bent portion 164 may be divided into an inclined portion 164a and an extending or extended portion 164b.

The inclined portion 164a may refer to a portion formed to be inclined along an inclined surface L of the insertion layer 180 to be described below. Additionally, the extending portion 164b may refer to a portion that extends outwardly from the inclined portion 164a.

The inclined portion 164a may be formed parallel to the inclined surface L of the insertion layer 180, and an inclination angle of the inclined portion 164a may be formed equal to that of the inclined surface L of the insertion layer 180.

At least a portion of the second electrode 170 may cover the piezoelectric layer 160 disposed on the top of the cavity C. The second electrode 170 may be used as either the input electrode or the output electrode for inputting or outputting the electrical signal such as the radio frequency (RF) signal. That is, when the first electrode 150 is used as the input electrode, the second electrode 170 may be used as the output electrode, and when first electrode 150 is used as the output electrode, the second electrode 170 may be used as the input electrode.

However, the second electrode 170 is not limited thereto, and may be formed using a conductive material such as molybdenum (Mo) or an alloy thereof, for example. However, the second electrode 170 is not limited thereto, and may be made of a conductive material such as ruthenium (Ru), tungsten (VV), iridium (Ir), platinum (Pt), copper (Cu), titanium (Ti), tantalum (Ta), nickel (Ni), chromium (Cr) or an alloy thereof.

When defining the resonance portion, the resonance portion may include the first electrode 150, the piezoelectric layer 160 and the second electrode 170, and may be a component vibrated by the piezoelectric effect of the piezoelectric layer 160.

The insertion layer 180 may be disposed between the first electrode 150 and the piezoelectric layer 160. The insertion layer 180 may be formed of a dielectric material such as silicon oxide (SiO₂), aluminum nitride (AlN), aluminum oxide (Al₂O₃), silicon nitride (Si₃N₄), manganese oxide (MgO), zirconium oxide (ZrO₂), lead zirconate titanate (PZT), gallium arsenide (GaAs), oxidation Hafnium (HfO₂), titanium oxide (TiO₂) and zinc oxide (ZnO), and made of a material different from that of the piezoelectric layer 160. Additionally, if necessary, a region may be formed in which the insertion layer 180 is disposed as an empty space (air). This configuration may be achieved by removing the insertion layer 180 in the manufacturing process.

The passivation layer 190 may be formed in a region of the resonance portion other than a region of the resonance portion where each of the first electrode 150 and the second electrode 170 are disposed. The passivation layer 190 may prevent damage to the second electrode 170 and the first electrode 150 during the manufacturing process.

Furthermore, the passivation layer 190 may be partially removed by etching to control a frequency in a final manufacturing process. That is, it is possible to adjust a thickness of the passivation layer 190. The passivation layer 190 may use a dielectric layer including any one of silicon nitride (Si₃N₄), silicon oxide (SiO₂), manganese oxide (MgO), zirconium oxide (ZrO₂), aluminum nitride (AlN), lead lithium titanate (PZT), gallium arsenide (GaAs), hafnium oxide (HfO₂), aluminum oxide (Al₂O₃), titanium oxide (TiO₂) and zinc oxide (ZnO), for example.

The metal pad 200 may be formed on a portion of each of the first electrode 150 and the second electrode 170 where the above passivation layer 190 is not formed. In an example, the metal pad 200 may be made of a material such as gold (Au), gold-tin (Au—Sn) alloy, copper (Cu), copper-tin (Cu—Sn) alloy, aluminum (Al) and aluminum alloy. In an example, the aluminum alloy may be an aluminum-germanium (Al—Ge) alloy. The metal pad 200 may include a first metal pad 202 connected to the first electrode 150 and a second metal pad 204 connected to the second electrode 170.

The cap 210 may be coupled to the substrate 110 to form an internal space together with the substrate 110. The cap 210 and the substrate 110 may be bonded to each other by a bonding member 104, and the bonding member 104 may be made of a metal material such as, but not limited to, tin (Sn) and gold (Au). In an example, the cap 210 may use the silicon wafer or the SOI type substrate.

Filling gas may be filled in an internal space S formed by the substrate 110 and the cap 210 of the bulk-acoustic wave filter device 100 according to an example, and the cavity C formed by the substrate 110 and the membrane layer 120. The filling gas may be a mixed gas including at least one of hydrogen gas and helium gas. In an example, the filling gas may be a mixture of the hydrogen gas and the helium gas, or a mixture of the hydrogen gas and nitrogen gas. However, the filling gas is not limited thereto, and may be another type of mixed gas including the hydrogen gas or the helium gas. Additionally, the filling gas may include only the hydrogen gas or only the helium gas.

Here, the description describes thermal conductivity (W/mK) for each type of gas.

TABLE 1

| Type of gas | Thermal conductivity (W/mK) |
|---|---|
| (dry) air | 0.026 |
| argon | 0.016 |
| carbon dioxide | 0.0146 |
| helium | 0.15 |
| hydrogen | 0.18 |
| krypton | 0.0088 |
| methane | 0.03 |
| nitrogen | 0.024 |
| saturated steam | 0.0184 |

In this manner, the filling gas may include the hydrogen gas and helium gas each having high thermal conductivity, and it is thus possible to improve heat dissipation efficiency by using the filling gas. That is, the nitrogen gas may be typically filled in the internal space formed by the cavity C, the substrate 110 and the cap 210, or the filling gas may not be filled in the internal space formed by the cavity C, the substrate 110 and the cap 210, and the internal space may thus be in a vacuum state. In this example, the heat dissipation efficiency through the internal space formed by the cavity C, the substrate 110 and the cap 210 may be decreased, and it may be beneficial to have more heat dissipation paths. However, the filling gas may include the hydrogen gas and the helium gas having the high thermal conductivity, and it is thus possible to improve the heat dissipation efficiency by using the filling gas.

The hydrogen gas or the helium gas included in the filling gas may be 5% or more of the total filling gas.

As described above, it is possible to improve the heat dissipation efficiency by using the filling gas including the hydrogen gas or the helium gas. Additionally, it is possible to improve the heat dissipation efficiency by using the filling gas, and thus a freedom degree in designing the filter device may not be limited. Therefore, it is possible to improve the heat dissipation efficiency without changing frequency characteristics.

A description is made of a method for confirming a component of the filling gas filled in the internal space formed by the cavity C, the substrate 110 and the cap 210.

First, in order to confirm the component of the filling gas filled in the internal space formed by the cavity C, the substrate 110 and the cap 210, it is possible to indirectly confirm the component of the filling gas using an inductively coupled plasma (ICP) spectrometry. That is, it may be confirmed that nitrogen is not used as the filling gas filled in the internal space formed by the cavity C, the substrate 110 and the cap 210 when no nitrogen or an extremely small amount of the nitrogen is detected using the ICP spectrometry.

As such, when the nitrogen is not used as the filling gas filled in the internal space formed by the cavity C, the substrate 110 and the cap 210, it is next possible to drive the bulk-acoustic wave filter device 100 and measure a temperature of the bulk-acoustic wave filter device 100. When the bulk-acoustic wave filter device 100 has a temperature lower than the typical bulk-acoustic wave filter device, it may be supposed that the filling gas including at least one of the helium gas and the hydrogen gas is used as the filling gas filled in the internal space formed by the cavity C, the substrate 110 and the cap 210.

In this example, it is possible to extract the filling gas filled in the bulk-acoustic wave filter device 100 and confirm the component of the filling gas using a gas chromatography. Accordingly, it may be possible to directly confirm that the filling gas including at least one of the helium gas and the hydrogen gas is used as the filling gas filled in the internal space formed by the cavity C, the substrate 110 and the cap 210.

The above description describes the method for indirectly confirming the component of the filling gas by using the ICP spectrometry and by measuring the temperature of the bulk-acoustic wave filter device 100 when the device 100 is driven, and then confirming the component of the filling gas using the gas chromatography. However, the method is not limited thereto. That is, if the component of the filling gas is to be confirmed, it may not be necessary to perform the ICP spectrometry or to measure the temperature of the bulk-acoustic wave filter device 100 when the device 100 is driven. The filling gas filled in the bulk-acoustic wave filter device 100 may be directly extracted and the component of the filling gas may be directly confirmed using the gas chromatography.

FIG. 2 illustrates a heat dissipation path of an example bulk-acoustic wave filter device, in accordance with one or more embodiments.

Referring to FIG. 2, the heat generated in the resonance portion may be externally radiated through the metal pad 200 and the external connection electrode 116 of the substrate 110. Additionally, the heat generated in the resonance portion may be transferred to the substrate 110 through the filling gas filled in the cavity C, and may then be externally discharged through the substrate 110. Additionally, the heat generated in the resonance portion may be transferred to the cap 210 through the filling gas filled in the internal space formed by the substrate 110 and the cap 210 and then externally discharged.

As such, the heat generated in the resonance portion may be discharged through the above three paths. The filling gas may be a mixed gas including the hydrogen gas or the helium gas. Accordingly, it is thus possible to improve the heat dissipation efficiency based on the heat discharged through the three paths.

As a result, it is possible to improve the overall heat dissipation efficiency of the bulk-acoustic wave filter device 100.

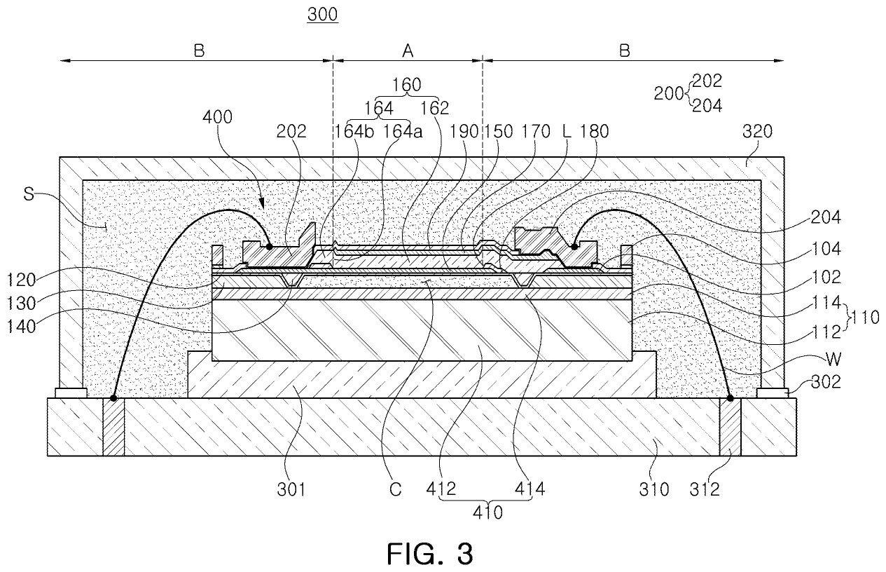

FIG. 3 is a schematic cross-sectional view illustrating a bulk-acoustic wave filter device according to another exemplary embodiment in the present disclosure.

Referring to FIG. 3, a bulk-acoustic wave filter device 300, in accordance with one or more embodiments, may include a package substrate 310, a volume acoustic resonator 400 and a cap 320.

In an example, the package substrate 310 may use the silicon wafer or the SOI type substrate. The package substrate 310 may have a via 312 connecting the volume acoustic resonator 400 to an external power source. The package substrate 310 may have the plurality of vias 312 each disposed outside the volume acoustic resonator 400.

The volume acoustic resonator 400 may be bonded to, and installed on, a top surface of the package substrate 310 by a bonding agent 301 made of epoxy or the like. The volume acoustic resonator 400 may include a substrate 410, the membrane layer 120, the sacrificial layer 130, the etch stop portion 140, the first electrode 150, the piezoelectric layer 160, the second electrode 170, the insertion layer 180, the passivation layer 190 and the metal pad 200.

The description here omits detailed descriptions of the membrane layer 120, the sacrificial layer 130, the etch stop portion 140, the first electrode 150, the piezoelectric layer 160, the second electrode 170, the insertion layer 180, the passivation layer 190 and the metal pad 200, which are the same components as those described above.

The substrate 410 may include a base 412 and a substrate protective layer 414 formed on a top surface of the base 412. The base 412 may be the silicon substrate. For example, the base 412 may use the silicon wafer or the silicon on insulator (SOI) type substrate.

The substrate protective layer 414 may be formed on the top surface of the base 412, and thus serve to electrically isolate the base 412 by being disposed on the top surface of the base. In addition, the substrate protective layer 414 may serve to prevent the base 412 from being etched by the etching gas when the cavity C is formed in a process of manufacturing the bulk-acoustic wave filter device 300.

In this example, the substrate protective layer 414 may be formed of at least one of silicon dioxide (SiO₂), silicon nitride (Si₃N₄), aluminum oxide (Al₂O₂) and aluminum nitride (AlN), and may be formed using any one of the chemical vapor deposition, the radio-frequency (RF) magnetron sputtering and the evaporation.

The substrate 410 may be bonded to, and installed on, the package substrate 310 by the bonding agent 301 made of epoxy or the like.

Additionally, the volume acoustic resonator 400 may be electrically connected to the package substrate 310 by wire bonding, and a wire W may connect the metal pad 200 with the via 312 of the package substrate 310.

Accordingly, heat generated in the resonance portion may be transferred to the via 312 through the wire W and then externally discharged.

The cap 320 may be coupled to the package substrate 310 to form an internal space together with the package substrate 310. The cap 320 and the package substrate 310 may be bonded to each other by a bonding member 302, and the bonding member 302 may be made of a metal material such as tin (Sn) and gold (Au). In an example, the cap 320 may use the silicon wafer or the SOI type substrate. The cap 320 may have the shape of a box having an open bottom end.

Meanwhile, filling gas may be filled in an internal space S formed by the package substrate 310 and the cap 320 of the bulk-acoustic wave filter device 300 according to an example, and a cavity C may be formed by the substrate 410 and the membrane layer 120. The filling gas may be a mixed gas including at least one of the hydrogen gas and the helium gas. For example, the filling gas may be a mixture of the hydrogen gas and the helium gas, or a mixture of the hydrogen gas and the nitrogen gas. However, the filling gas is not limited thereto, and may be another type of mixed gas including the hydrogen gas or the helium gas. In addition, the filling gas may include only the hydrogen gas or only the helium gas.

Accordingly, the filling gas may include the hydrogen gas and the helium gas each having high thermal conductivity, and it is thus possible to improve the heat dissipation efficiency by using the filling gas.

Meanwhile, the hydrogen gas or the helium gas included in the filling gas may be 5% or more of the total filling gas.

As described above, it is possible to improve the heat dissipation efficiency by using the filling gas including the hydrogen gas or the helium gas. Additionally, heat dissipation efficiency may be improved by using the filling gas, and thus a freedom degree in designing the filter device may not be limited. Therefore, it is possible to improve the heat dissipation efficiency without changing frequency characteristics.

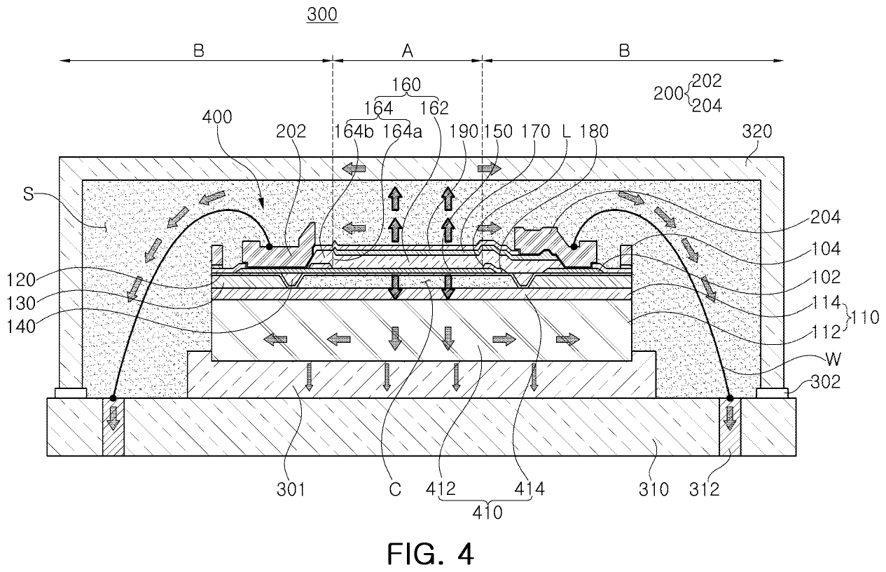

FIG. 4 illustrates a heat dissipation path of an example bulk-acoustic wave filter device, in accordance with one or more embodiments.

Referring to FIG. 4, the heat generated in the resonance portion may be discharged through at least three paths. In an example, the heat generated in the resonance portion may pass through the metal pad 200 and the wire W, and may then be externally discharged through the via 312 of the package substrate 310. Additionally, the heat generated in the resonance portion may be transferred to the substrate 410 through the filling gas filled in the cavity C, and the heat transferred to the substrate 410 may be transferred to the package substrate 310 through the bonding agent 301 and then externally discharged. Additionally, the heat generated in the resonance portion may be transferred to the cap 320 through the filling gas filled in the internal space formed by the package substrate 310 and the cap 320 and then externally discharged.

As such, the heat generated in the resonance portion may be discharged through the above three paths. The filling gas may be a mixed gas including the hydrogen gas or the helium gas. Accordingly, it is thus possible to improve the heat dissipation efficiency based on the heat discharged through the three paths.

As a result, it is possible to improve the overall heat dissipation efficiency of the bulk-acoustic wave filter device 300.

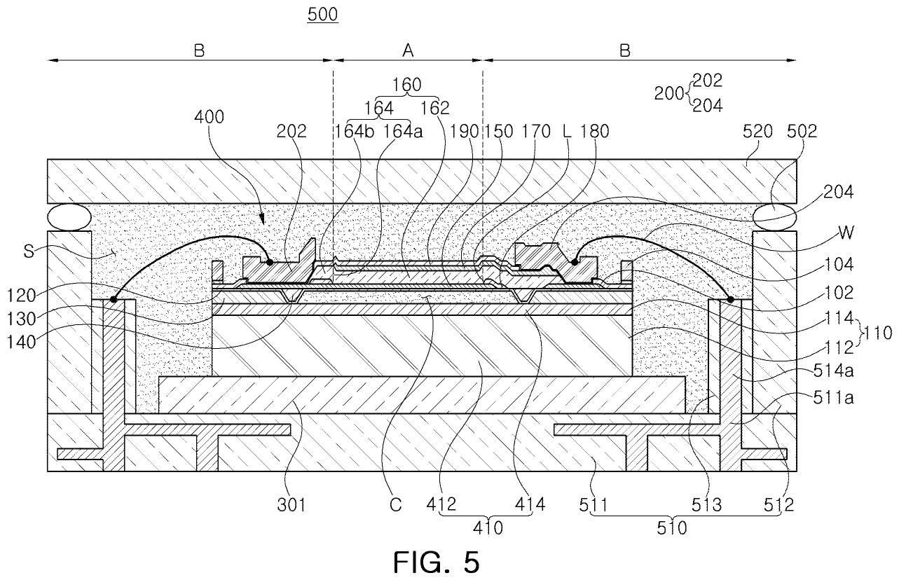

FIG. 5 is a schematic cross-sectional view illustrating an example bulk-acoustic wave filter device, in accordance with one or more embodiments.

Referring to FIG. 5, an example bulk-acoustic wave filter device 500, in accordance with one or more embodiments, may include a package substrate 510, the volume acoustic resonator 400 and a cap 520.

The description here omits a detailed description of the volume acoustic resonator 400 which is substantially the same component as that described above.

The package substrate 510 may be implemented with the silicon wafer or the silicon on insulator (SOI) type substrate. The package substrate 510 may have a plate portion 511, an outer wall portion 512 extending from an edge of the plate portion 511 and bonded to the cap 520, and an inner wall portion 514 disposed inside the outer wall portion 512. The inner wall portion 514 may have a height lower than the outer wall portion 512.

Additionally, a first via 514a electrically connected to the volume acoustic resonator 400 may be disposed in the inner wall portion 514, and a second via 511a connected to the first via 514a may be disposed in the plate portion 511.

The volume acoustic resonator 400 may be electrically connected to the package substrate 510 by wire bonding, and a wire W may connect the metal pad 200 with the first via 514a disposed in the inner wall portion 514 of the package substrate 510.

Accordingly, heat generated in the resonance portion may be transferred to the first and second vias 514a and 511a through the wire W, and may then be externally discharged.

In an example, the package substrate 510 may have the shape of a box having an open top end.

The cap 520 may be coupled to the package substrate 510 to form an internal space together with the package substrate 510. The cap 520 and the package substrate 510 may be bonded to each other by a bonding member 502, and the bonding member 502 may be made of the metal material such as tin (Sn) and gold (Au). In an example, the cap 520 may use the silicon wafer or the SOI type substrate. The cap 520 may substantially have a plate shape.

Filling gas may be filled in an internal space S formed by the package substrate 510 and the cap 520 of the bulk-acoustic wave filter device 500 according to an example, and the cavity C formed by the substrate 410 and the membrane layer 120. The filling gas may be a mixed gas including at least one of the hydrogen gas and the helium gas. In an example, the filling gas may be a mixture of the hydrogen gas and the helium gas, or a mixture of the hydrogen gas and the nitrogen gas. However, the filling gas is not limited thereto, and may be another type of mixed gas including the hydrogen gas or the helium gas. Additionally, the filling gas may include only the hydrogen gas or only the helium gas.

Accordingly, the filling gas may include the hydrogen gas and the helium gas each having the high thermal conductivity, and it is thus possible to improve the heat dissipation efficiency by using the filling gas.

The hydrogen gas or the helium gas included in the filling gas may be 5% or more of the total filling gas.

As described above, it is possible to improve the heat dissipation efficiency by using the filling gas including the hydrogen gas or the helium gas. In addition, it is possible to improve the heat dissipation efficiency by using the filling gas, and thus a freedom degree in designing the filter device may not be limited. Therefore, it is possible to improve the heat dissipation efficiency without changing frequency characteristics.

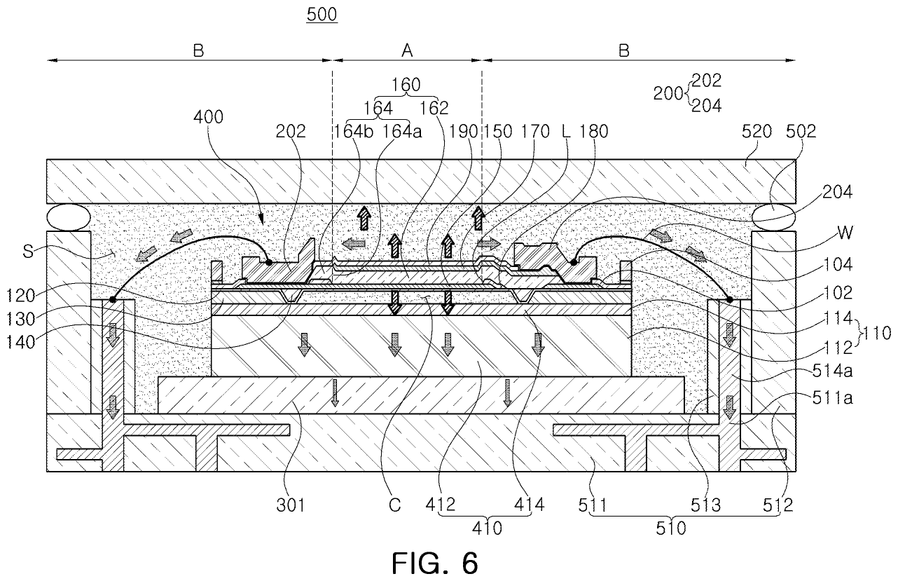

FIG. 6 illustrates a heat dissipation path of an example bulk-acoustic wave filter device, in accordance with one or more embodiments.

Referring to FIG. 6, heat generated in the resonance portion may pass through the metal pad 200 and the wire W, and may then be externally discharged through the first and second vias 514a and 511a of the package substrate 510. Additionally, the heat generated in the resonance portion may be transferred to the substrate 410 through the filling gas filled in the cavity C, and the heat transferred to the substrate 410 may be transferred to the package substrate 510 through the bonding agent 301 and then externally discharged. Additionally, the heat generated in the resonance portion may be transferred to the cap 520 through the filling gas filled in the internal space formed by the package substrate 510, and the cap 520 and may then be externally discharged.

As such, the heat generated in the resonance portion may be discharged through the above three paths, and the filling gas may be a mixed gas including the hydrogen gas or the helium gas, it is thus possible to improve the heat dissipation efficiency of the heat discharged through the three paths.

As a result, it is possible to improve the overall heat dissipation efficiency of the bulk-acoustic wave filter device 500.

As set forth above, the examples may provide the bulk-acoustic wave filter device having improved heat dissipation characteristics.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A bulk-acoustic wave filter device, comprising:
a substrate;
a resonance portion, in which a cavity is disposed between the substrate and the resonance portion; and
a cap, configured to form an internal space together with the substrate,
wherein filling gas, including at least one of hydrogen gas and helium gas, is filled in at least one of the cavity and the internal space formed by the substrate and the cap.

2. The bulk-acoustic wave filter device of claim 1, wherein the filling gas is a mixture of the hydrogen gas and the helium gas.

3. The bulk-acoustic wave filter device of claim 1, wherein the filling gas is a mixture of the hydrogen gas and nitrogen gas.

4. The bulk-acoustic wave filter device of claim 1, wherein the hydrogen gas or the helium gas is 5% or more of the filling gas.

5. The bulk-acoustic wave filter device of claim 1, wherein the resonance portion comprises:
a first electrode, at least a portion of which is disposed on a top surface of the cavity;
a piezoelectric layer, disposed to cover at least a portion of the first electrode; and
a second electrode, at least a portion of which is disposed to cover the piezoelectric layer.

6. The bulk-acoustic wave filter device of claim 5, further comprising an external connection electrode, disposed to penetrate through the substrate, and configured to be electrically connected to the first electrode and the second electrode.

7. The bulk-acoustic wave filter device of claim 5, further comprising:
a membrane layer, configured to form the cavity together with the substrate, and on which the first electrode is disposed;
an etch stop portion, disposed to surround the cavity;
a passivation layer, disposed to cover a region of the resonance portion other than a region of the resonance portion where each of the first electrode and the second electrode are disposed; and
a metal pad connected to each of the first electrode and the second electrode.

8. The bulk-acoustic wave filter device of claim 7, further comprising an insertion layer, at least a portion of which is disposed between the piezoelectric layer and the first electrode.

9. A bulk-acoustic wave filter device, comprising:
a package substrate;
a volume acoustic resonator, mounted on the package substrate; and
a cap, configured to form an internal space together with the package substrate,
wherein the volume acoustic resonator comprises:
a substrate, mounted on the package substrate;
a first electrode,
a cavity, disposed between the substrate and the first electrode;
a piezoelectric layer, disposed to cover at least a portion of the first electrode; and
a second electrode, disposed to cover at least a portion of the piezoelectric layer, and
wherein filling gas, including at least one of hydrogen gas and helium gas, is filled in at least one of the cavity and the internal space formed by the package substrate and the cap.

10. The bulk-acoustic wave filter device of claim 9, wherein the filling gas is a mixture of the hydrogen gas and the helium gas.

11. The bulk-acoustic wave filter device of claim 10, wherein the filling gas is a mixture of the hydrogen gas and nitrogen gas.

12. The bulk-acoustic wave filter device of claim 10, wherein the hydrogen gas or the helium gas is 5% or more of the filling gas.

13. The bulk-acoustic wave filter device of claim 9, wherein the volume acoustic resonator further comprises a metal pad connected to each of the first electrode and the second electrode, and
the package substrate is configured to have a via connected to the metal pad by wire bonding.

14. The bulk-acoustic wave filter device of claim 9, wherein the volume acoustic resonator further comprises a metal pad connected to each of the first electrode and the second electrode, and
the package substrate is configured to have an inner wall portion in which a first via connected to the metal pad by wire bonding is formed.

15. The bulk-acoustic wave filter device of claim 14, wherein the package substrate is configured to have a second via connected to the first via, and the second via is exposed to a bottom surface of the package substrate.

16. The bulk-acoustic wave filter device of claim 9, wherein the volume acoustic resonator further comprises:
a membrane layer, configured to form the cavity together with the substrate, and on which the first electrode is disposed;
an etch stop portion, disposed to surround the cavity;
a passivation layer, disposed to cover a region of the resonance portion other than a region of the resonance portion where each of the first electrode and the second electrode are disposed;
a metal pad, connected to each of the first electrode and the second electrode; and
an insertion layer, at least a portion of which is disposed between the piezoelectric layer and the first electrode.

17. A bulk-acoustic wave filter device, comprising:
a substrate;
a resonance portion, comprising a first electrode, a piezoelectric layer, and a second electrode, arranged sequentially;
a cavity, disposed between the first electrode and the substrate; and
a cap, configured to form an internal space with the substrate,
wherein a gas including at least one of hydrogen gas and helium gas is filled in the cavity and the internal space.

18. The bulk-acoustic wave filter device of claim 17, wherein the gas is a mixture of the hydrogen gas and nitrogen gas.

19. The bulk-acoustic wave filter device of claim 17, wherein the hydrogen gas or the helium gas is 5% or more of the gas.
